(19) United States
(12) Patent Application Publication
(10) Pub. No.: US 2008/0290511 A1
(43) Pub. Date: Nov. 27, 2008

(54) Chip Assembly and Method of Manufacturing Thereof

(75) Inventors: Nicolaas Johannes Anthonius Van Veen, Eindhoven (NL); Ronald Dekker, Eindhoven (NL); Coenraad Cornelis Tak, Nijmegen (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 12/093,336

(22) PCT Filed: Nov. 7, 2006
(86) PCT No.: PCT/IB2006/054149

§ 371 Date: May 12, 2008

(30) Foreign Application Priority Data
Nov. 11, 2005 (EP) 05110653.2

(51) Int. Cl. H01L 21/50; H01L 23/48

(52) U.S. Cl. 257/737; 438/107; 257/E23.01; 257/E21.499

(57) ABSTRACT

An assembly of a first chip (100) and a second chip (200), which first chip (100) is flexible and is provided with a first and a second resin layer (12, 52) on opposite sides (1, 2) of the chip (100), which allows to keep the first chip under compressive conditions, on which first and second side (1,2) respectively first side contact pads (33) and second side contact pads (31) are present, which first side contact pads (33) are coupled to corresponding contact pads (211) of the second chip (200), and which second side contact pads (31) are designed for external connection of the assembly.

The invention relates to an assembly of a first and a second chip.

The invention also relates to a method of manufacturing an assembly of a first and a second chip, comprising the steps of:

attaching a first wafer having a semiconductor substrate with a plurality of the first chips to a carrier;

thinning the semiconductor substrate;

attaching a second wafer having a semiconductor substrate with a plurality of the second chips to the thinned semiconductor substrate of the first wafer; and opening contact pads so as to enable external connection to the assembly.

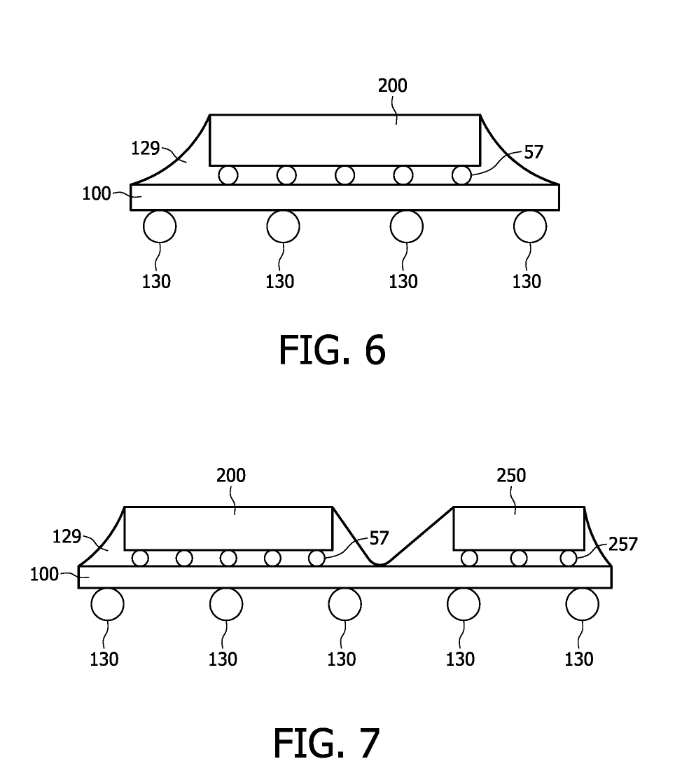

Such an assembly and such a method are known from U.S. Pat. No. 6,506,664. FIG. 6 of this known document discloses an embodiment that is particularly useful for the production of three-dimensional memory units. The fully processed first wafer having a semiconductor substrate and active and/or passive devices thereon is attached to the carrier by a release layer, and then thinned by conventional techniques, such as chemical or mechanical grinding and/or polishing. Then the second wafer is attached to the thinned side of the first wafer using an adhesive layer. For this adhesive layer a polymer adhesive layer such as BCB that is softened by heating, is chosen. The second wafer is thereafter thinned to a thickness of 5 to 25 microns. This process of attachment and thinning is repeated to obtain a stack of device layers mutually attached with adhesive layers and attached to a carrier via a release layers. This stack is further heated to a temperature of 120° C. to bake the adhesive layers and make them resistant to solvents such as acetone. After removal of the carrier, the stack is then baked to completely cross-link the adhesive layers. Finally, a groove is formed through all the layers of the stack, which groove allows access to all of the bonding pads designed in the layers of the stack. This groove can then be provided with a metallization to contact the bonding pads.

It is a disadvantage of the known assembly, that the provision of contacts through a groove is a process that requires a minimum resolution of the metallization. Also, it requires a specific design so as that the bond pads are adequately disposed and that sufficient bond pads can be exposed in a single layer.

It is therefore a first object of the invention to provide an assembly in which coupling of the assembly to for instance an external carrier is improved and particularly simplified, such that a groove is not needed.

This object is achieved in that the first chip is flexible and is provided with a first and a second resin layer on opposite sides of the chip, which allows to keep the first chip under compressive conditions, on which first and second side respectively first side contact pads and second side contact pads are present, which first side contact pads are coupled to corresponding contact pads of the second chip, and which second side contact pads are designed for external connection of the assembly.

In the invention, the use of a groove is circumvented by the provision of contact pads on both opposite sides of the first chip. The assembly may thus be contacted from the second side contact pads of the first chip. Effectively, these are located similarly to contact pads of a single chip, which implies that there is no need to modify the assembly process.

The design of the second side contact pads so as to be suitable for external connection of the assembly may in particular be either a design suitable for wirebonding or a design suitable for the provision of solder balls for direct contact to a printed circuit board or an alternative carrier. The design for wirebonding requires a sufficient strength of the contact pads and the underlying structure. The design for the provision of solder balls requires the possibility to release stresses in one or more layers. Additionally the size and the pitch of the solder balls should match with that of the printed circuit board.

A further feature of the first chip is its inherent flexibility. This means that the chip does not constitute a rigid body and can be bent and/or otherwise deformed in the direction normal to its first and second side. The use of such a chip, hereinafter also referred to as a ‘flexible chip’, improves the stress relaxation during thermal cycling. The rate of stress relaxation in a flip chip structure depends on the assembly stiffness and the deformation properties of the solder. The deformation properties of the solder will in many applications of the present assembly be relatively limited, in view of the small pitch and small size of the solder joint connections between the first and the second chip. Both a low thickness and flexibility, e.g. low elastic modulus, of the first chip however contribute to a low assembly stiffness.

In order to provide an inherent flexibility, but still allow the presence of functional elements in the chip of inorganic materials, it is desired to put the first chip under compressive strain. Such compressive strain is suitably achieved in that at both sides of the functional elements, a resin layer is provided, such as for instance a layer of polyimide, a flexible epoxy, a polyacrylate or the like. Most suitably, the contact pads are present on top of the resin layers, such that merely vertical interconnects extend through the resin layers. An example of such a chip is described in the non-prepublished application EP 05101593.1 (PHNL050169), which is herein incorporated by reference. The resulting mismatch between the coefficients of thermal expansion of the resin layers of the first chip, and as such the complete first chip, and the second chip may of course be reduced with the addition of fillers in the resin layer to reduce the coefficient of thermal expansion and/or the addition of additives to improve the thermal conductivity. Additionally, an underfill material is suitably provided between the first and the second chip. However, exactly because the first chip has an inherent flexibility, deformation of the second chip may take place and stresses can be distributed over a larger area and be kept within acceptable limits.

It is observed that U.S. Pat. No. 6,506,664 and U.S. Pat. No. 6,027,958 disclose stacking methods for thinned chips, in which the chips are embedded in a thin-film network. Individual network may be stacked, while electrical connections are provided between the thin-film networks. This is done with thin-film techniques known from the interconnect structure of an integrated circuit, e.g. with a vertical interconnects. However, for assemblies fitting into the conventional assembly processes, the stackable thin-film network is too large, and as a result too expensive. Also, the coupling method is not a technique applied in industrial assembly processes. Moreover, although internal contacts are shown, there are no contact pads for external connection on the top side.

In a first embodiment, the second side contact pads have a larger diameter than the first side contact pads. As a result, also the contact pads at the second chip, corresponding to the first side contact pads, can be effectively reduced. This is advantageous in order to miniaturize the chip size or to have sufficient input/outputs. The second side contacts may well be larger in that some of them extend to the devices within the first chip, and there are thus effectively less second side contact pads than first side contact pads. Additionally, the presence of the first chip allows to do additional rerouting of interconnects. Rerouting is an important issue in packaging, so as to modify not only the size of the contact pads, but also their location and their mutual distance. As such, the contact pads may be divided over the second side as uniform as possible.

In the first, wire-bonding embodiment as mentioned above, the first chip may have smaller lateral dimensions than the second chip or could have equal lateral dimensions.

In the case that the first chip has equal lateral dimensions as the second chip, wafer level assembly is possible. This effectively reduces assembly cost. Suitably, any electrical connections between the first and second chip are then formed with a wafer-scale technique, for instance the provision of stud bumps grown by electroplating or electroless processing, the use of an anisotropically conductive adhesive, or the use of any other technique with conducting particles within a matrix. A very suitable choice for forming a connection is the use of a solder cap. Such a solder cap has a reduced height, and hence can have a reduced diameter as well, in the order of 1 to 30 microns. Opposite to the solder cap a metallization provided with electroplating, electroless processing or another technique is suitable. Most suitable is a solder cap that can be provided by immersion in a bath.

In the case that the first chip has smaller lateral dimensions than the second chip, additional contact pads may be present on the second chip adjacent to those underlying the first chip. This construction appears to be advantageous for various reasons; first, the first chip may be assembled to the second chip in a chip area overlying the active elements. Conventionally, any contact pads in this area are sensitive so as to bring damage to the underlying active elements. The first chip, particularly if it has inherent flexibility, now enables to distribute the stresses of the wirebonding operation so that damage to the active elements of the second chip is prevented. The fragility of the second chip is even enhanced, if its interconnect structure comprises so-called low-K materials. These materials, that are often of a polymeric nature and may be porous, tend to have a limited adhesion, and hence form weak parts that may delaminate due to the stresses resulting from wirebonding. Another advantage of the provision of a second chip on top of the first chip is constituted by the difference in height. This appears relevant for an adequate guidance of the bond wires to any chip carrier, such that every bond wires is effectively separate: with the height difference the risk that bond wires from the inner bond pads tend to contact, and form short-circuits with, bond wires from the outer bond pads, is reduced. A further advantage is that for certain connections, such as power and grounding, still a most direct connection to the second chip may be established, e.g. through the additional contact pads.

With this first, wirebonding embodiment, it is suitable that the assembly is part of an electronic device further comprising a chip carrier. As will be understood by the skilled person, the bottom side of the second chip is attached therein to the chip carrier with a suitable die attach material. The chip carrier will have adequate terminals for coupling to an external component. The carrier may be for instance a laminate, a tape and a leadframe. The use of the chip assembly in combination with a leadframe appears advantageous; passive components and other functions that tend to be integrated into the laminate, and therewith increase the price thereof, can now be put into the first chip. Therewith the distance between the passive components and the second chip is reduced, which is suitable for many applications. One application is for instance the use of capacitors in combination with a second chip for RF applications, such as a transceiver, a power amplifier or the like. An alternative application is the provision of resistors and the like in combination with a digital integrated circuit.

In the second embodiment, the first chip generally forms the carrier for the second chip. The first chip suitably has equal or larger lateral dimensions than the second chip. The embodiment in which the first chip has smaller lateral dimensions, is however not excluded. If the lateral dimensions are equal, a chip-scale package construction is obvious. If the lateral dimensions of the first chip are larger, the first chip may be the chip carrier of the second chip. The second chip may then be attached to the first chip in any conventional manner: face up (with electrical connections in the form of bond wires, a flexible tape, such as a tape-automated-bonding (TAB) technique or otherwise) face down. In both cases, more than one chip may be assembled to the first chip. In this second embodiment, it is clearly an advantage that the first chip is provided with an inherent flexibility. Most suitably, the resin of the first chip is chosen such that the coefficient of thermal expansion of the first chip lies between that of the second chip and that of the printed circuit board.

The devices in the first chip may be of different kinds. Usually, the second chip will form an integrated circuit. Generally, one may distinguish passive devices, such as decoupling capacitors and resistors; the technical advantage hereof is that such passive devices are needed very near to modern integrated circuits. In this manner, the number of I/Os can be effectively reduced, while these devices may nevertheless be provided on a low cost substrate in a relatively low-cost process

A second category is formed by the additional active devices, such as memory devices, bipolar devices. The advantage of separating these is that different technologies are needed to make them; the assembly of separate chips is then easier than the integration in one single process.

A third category of devices are formed by peripheral devices, such as ESD-protections, power devices, identification devices. Advanced integrated circuits have a very high density, so as to lead to effective miniaturization. However, in order that they function adequately, several functions are needed that cannot be miniaturized as much as the transistors of the integrated circuits. Thus, in view of the difference in device size, it makes more sense to put these peripherals in separate chips. Additionally, it inherently makes sense to put these peripherals in separate chips, as they may function as entry devices and need additional technological features, such as a very good grounding, a heat sink and the like.

This object is further achieved in the method mentioned in the opening paragraph.

A suitable embodiment is characterized in that:

the first wafer is provided with first side contact pads and second side contact pads, which first side contact pads are exposed after the thinning of the semiconductor substrate and are electrically coupled to bond pads in the second wafer in the attachment step, and

the assembly is detached from the carrier in order to open the second side contact pads for enabling external connection.

In this embodiment of the method of the invention, the first wafer is applied as a wafer-level functional interposer. Thereto, the first and the second wafer are provided with electrical connections between each other. There is therefore no need to apply grooves and a metallization therein to end at one surface.

Additionally, the use of this wafer-level interposer has the advantage that it may be combined very well with second wafers of an advanced type. Such an advanced type comprises transistors with small channel length of less than 100 nm, and corresponding resolution in one or more interconnect layers thereon. In effect, part of the interconnect structure may be replaced from the second wafer to the first wafer. Moreover, such advanced type semiconductor device often comprises a dielectric material with a low dielectric constant, particularly a relative dielectric constant of less than 2.5. This type of dielectric material may be of the type known as ‘low-K’-material or alternatively an air gap. Its disadvantage is however reduced mechanical stability. This reduced mechanical stability provides large problems for the assembly process, and particularly for wirebonding. By stacking the wafers, no wirebonding is applied directly to the second wafer, which considerably reduces the assembly problems.

The separation of the wafers into individual chip assemblies is carried out after that the mutual attachment of the first and second wafer. This can be done before or after removal of the carrier. Additionally, the second wafer could be attached to a tape commonly used in dicing processes before removal of the carrier.

In a suitable embodiment, the first and the second wafer are provided with trenches that are filled with a filling material and that after the thinning step extend from the first side to the second side of the wafers, and wherein the assembly is individualized by removal of the filling material from the trenches and subsequent at least local removal of the assembly from the carrier. This embodiment provides a wafer-level method of the separation. As it is an etching process, the width of the separation lanes can be reduced in comparison to separation lanes needed with sawing or laser scribing techniques. It is a requirement of this method, that also the second wafer is thinned.

The second side contact pads may be provided with solder before the attachment of the first wafer to the carrier or after removal of the carrier. Particularly, if the resulting assembly of the first and the second chip is flexible, due to its total thickness and in case of absence of any rigid semiconductor substrates, it appears suitable that the solder is applied before the attachment. The use of solder caps, optionally in combination with stud bumps, is then advantageous.

These and other aspects of the assembly of the invention will be further illustrated with reference to the figures, that are purely diagrammatical and in which equal reference numbers in different figures refer to like parts, of which:

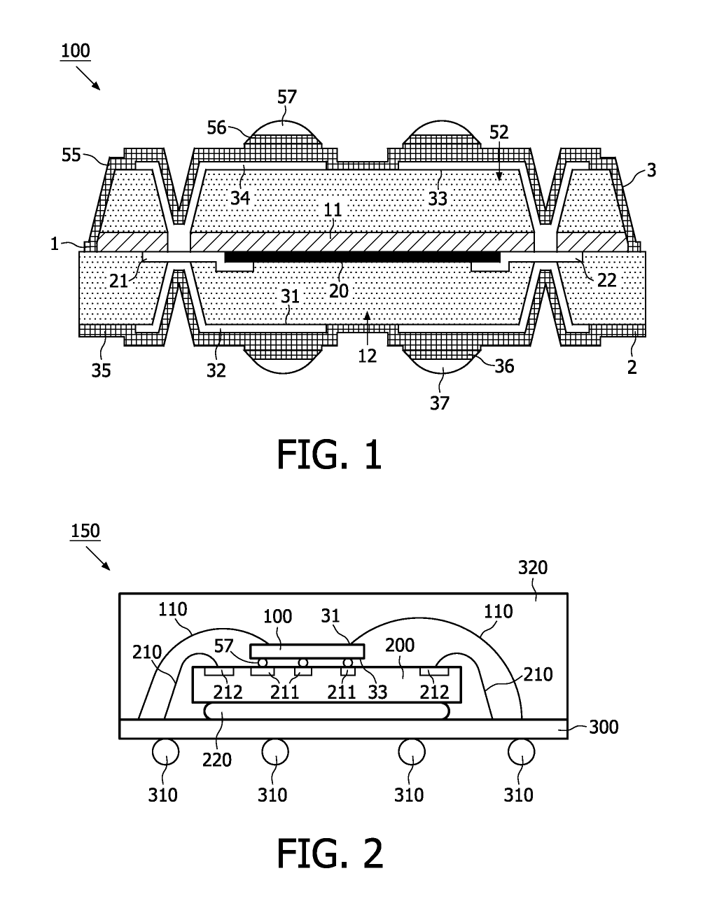

FIG. 1 shows a cross-sectional view of a first chip suitable for use in the assembly of the invention, and

FIGS. 2-9 show cross-sectional views of several assemblies of the invention.

FIG. 1 shows the first chip 100 in one embodiment. The device 100 comprises a first side contact pad 33 and a second side contact pad 31, as well as an integrated circuit 20. The integrated circuit 20 is present between a first and a second resin layer 52,12 that put the circuit under compressive strain so as to minimize crack formation. Conducting tracks 32, 34 extends through resin layers 12,52 respectively to via pads 21,22. In this example, the conducting tracks 32,34 are connected to the same via pad 21, 22, leading to a package that can be applied from two sides 1,2. However, this is an example only, and it will be clear that in practice the conducting tracks 32,34 are displaced with respect to each other. The conducting tracks 32,34 end up at contact pads 31, 33, which are exposed partially (‘resist defined pads’) through passivation layers 35,55. The contact pads 31,33 are strengthened with under bump metallizations 36,56 and provided with bumps 37, 57, in this case solder caps. The passivation layer 55 also extends at a lateral side face 3 of the first chip 100 up to insulating layer 11. The other resin layer at the second side 2 of the first chip 100 is separated using conventional separation technology such as sawing or cutting.

In this example, use is made of a semiconductor substrate 10 in which an insulating layer 11 is buried. The buried layer 11 is typically an oxide layer, but may include a nitride layer for improved chemical protection of the integrated circuit 20, which is provided in and on a surface layer of a semiconductor material that is generally epitaxially grown. The semiconductor material of the substrate 10 and the surface layer are in this case silicon, but the surface layer could be alternatively another semiconductor material, such as GaAs or GaN. The buried insulating layer 11 is used in the process as an etch stop layer. Alternatively, an p-n junction may be used as an etch stop layer. In another example, not shown here, use is made of a conventional substrate, with an thermal oxide thereon, that is commonly made by local oxidation of silicon (LOCOS). Semiconductor devices may then be defined for instance in a thin-film technology on the oxide. These devices may be applied as wells in the substrate, such as for instance in CMOS or BICMOS technology. During the etching treatment, portions of the semiconductor substrate are then kept as mesa-structures. Alternatively, the first chip 100 may contain only passive elements, such as capacitors, resistors and inductors. Due to the absence of the silicon substrate, substrate interactions are absent and inductors of a high-Q value can be prepared. The capacitors may be in the form of trench capacitors, if higher capacitance densities are desired. Although in this example the silicon substrate is removed as far as possible, this is not strictly necessary. A chip with a substrate of for instance 20 microns, in which apertures are present to expose bond pads may be used alternatively.

For the resin layers 12,52 use is made of polyimide in a typical thickness of 10 to 20 μm. Before applying the polyimide, for instance by spincoating, the surface has been cleaned and a primer layer has been provided for improved adhesion. After the application of the polyimide, it is heated first to 125° C. and thereafter to 200° C. Then a photoresist is applied, exposed to a suitable source of radiation and developed. The development includes the structuring of the polyimide layer, so as to create contact windows that expose the first and second via pads 21, 22. The second resin layer 12 of polyimide is removed as well in an edge area C of the substrate, typically a 6″ wafer. The removal of the support layer 13 in the edge area C has an beneficial effect on the yield. The resin layers 12,52 may contain the same material, but that is not necessary. The resin layers may further comprise strengthening materials such as fibers, particularly aramid fibers, carbon fibers or glass fibers. Alternatively, the resin layers may comprise thermally conductive fillers, such as aluminum nitride, aluminum oxide, boron nitride and even copper particles with an oxidized surface.

The passivation layer 35,55 is in this case silicon nitride and is deposited by PECVD at a temperature of about 250° C., in a thickness of approximately 0.5-1.0 micron. Thereafter, the passivation layer 35 is patterned to expose the contact pads 31. The passivation layer 35 partly extends on the contact pads 31, and functions as a ‘resist defined’ solder mask. The contact pad 31 is thereafter strengthened by deposition of an under bump metallization 36. In this example, the under bump metallization 36 comprises nickel and is deposited electroless in a thickness of 2-3 microns. This treatment has the advantage, that no additional mask is needed for the provision of the under bump metallization 36. Alternatively, copper can be used for the under bump metallization 36 and be applied by electroplating. In this case, the under bump metallization 36 and a galvanic bump 37 may be applied in one step. Due to its thickness the under bump metallization 36 extends over the passivation layer 35.

The bump 37 is applied on the under bump metallization 36. In this example, the bump 37 is a solder cap of Sn, SnBi or PbSn, and is applied by immersion into a bath of the desired composition. However, if this under bump metallization 36 is immersed in a bath of pure tin at a temperature of approximately 250° C., then NiSn intermetallics may be formed. And they are formed in the form of needles that protrude through the bump surface. This does not give a useful result. The formation of these intermetallics can be prevented through the use of a low-melting Sn-alloy. Examples of such alloys include SnPb, SnCu and SnBiₓIn_{y}Zn_{z}, wherein at least one of x, y and z is larger than zero. Preferably, a lead-free solder is applied. Advantageously, the alloying elements do not interfere in the reaction between Sn and the metal of the metallization—particularly Au.

FIG. 2 shows a first embodiment of the electronic device 150. Herein the assembly of first chip 100 and second chip 200 is combined with a carrier 300 into a package. The first chip 100 and the second chip 200 are mutually electrically coupled with solder balls 57 that are present between first side contact pads 33 in the first chip 100 and corresponding contact pads 211 in the second chip 200. The second chip 200 is attached to the carrier 300 with its bottom side through a die attach layer 220. Not shown, but suitably, the space between the first chip 100 and the second chip 200 is filled with an underfill material. Second side contact pads 31 in the first chip 100 are present at the second side. Wirebonds 110 form connections between these second side contact pads 31 and conducting traces on the carrier 300. This carrier is typically a laminate or a leadframe as known per se to the skilled person. The second chip 200 comprises additional contact pads 212 adjacent to those contact pads 211 underlying the first chip 100. These contact pads are in this suitable example provided in the periphery of the second chip 200, such that they do not overlie any active elements—not shown—in the second chip 200. Suitably, the additional contact pads 212 have a larger diameter and a strengthened underlying structure, such that they are suitable for wirebonding. Wires 210 are provided between these additional contact pads 212 and conductive traces on the carrier 300. A mould 320 is provided on the carrier so as to encapsulate the first chip 100, the second chip 200 and the bond wires 110,210. Solder balls 310 are provided on the bottom side of the carrier for placement on an external component, in particular a printed circuit board.

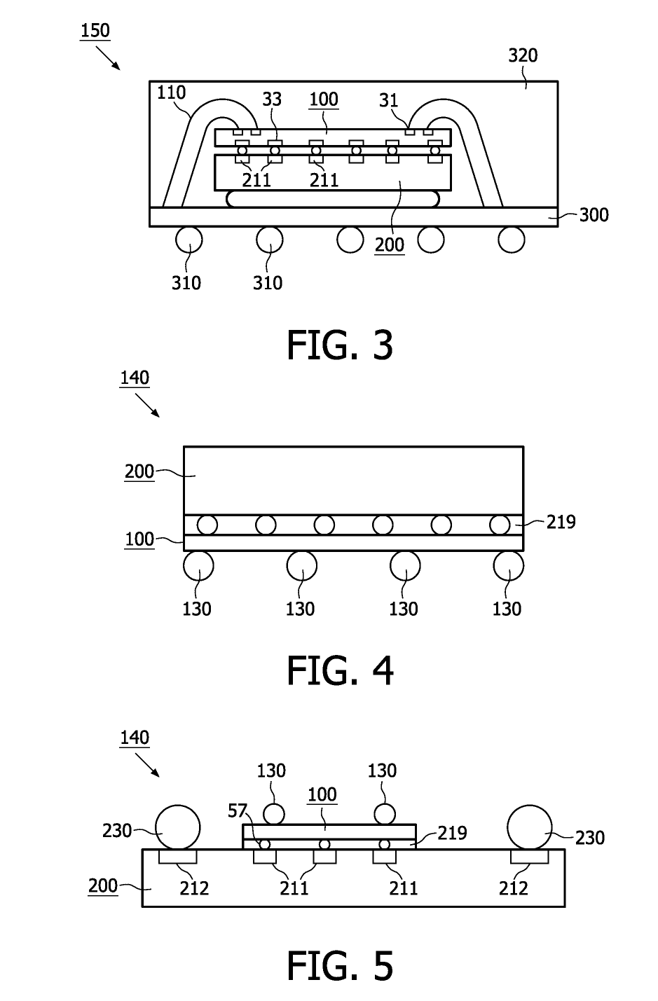

FIG. 3 shows a second embodiment of the device 150, comprising again the first chip 100, the second chip 200 and an external carrier 300. The first chip 100 and the second chip 200 have an equal lateral extension in this embodiment. This facilitates assembly in the sense that separation can be carried out after that a wafer with first chips 100 and a wafer with second chips 200 have been assembled together. Thereto, in both wafers, separation lanes have been prepared with etching techniques. After temporary filling these separation lanes, the assemblies may be singulated using any suitable separation technique including both etching and sawing

FIG. 4 shows a further embodiment of the assembly 140. In this example no additional carrier is present. The assembly 140 is designed for use as a chip scale package. The solder balls 130 are chosen to be suitable for direct placement on a printed circuit board. An underfill material 219 is herein shown to be present between the first chip 100 and the second chip 200 and to encapsulate the solder ball connections. As will be understood, it is particularly suitable that the first chip 100 and the second chip 200 cooperate, since then the number of solder balls 130 can be reduced in comparison to the number of solder balls 57. Therewith, the pitch between solder balls 130 can be substantially larger and the height of the solder balls 130 can be substantial. A height usually applied in such chip scale packages appears optimal.

FIG. 5 shows a second embodiment of such an assembly 140. Herein, the first chip 100 has a smaller lateral extension than the second chip 200. Solder balls 230 are provided on the additional contact pads 212 of the second chip. In order that the assembly is functional, the height of the solder balls 230 needs to be equal to the height of the solder balls 130, the first chip 100 and the solder balls 57 between the first chip 100 and the second chip 200. It is thereto suitable to use small sized solder balls 57, preferably solder caps, and a very thin first chip 100. Additionally, the contact pad 212 can be brought upwards through an additional metallization level or a thicker underbump metallization.

FIG. 6 shows a third embodiment of such an assembly 140, that is similar to the embodiment of FIG. 5. In this embodiment, the first chip 100 laterally extends beyond the second chip 200. Therewith, it is suitable for acting as a conventional chip carrier. The encapsulation 129 ensures that the assembly is well sealed against moisture and dust.

FIG. 7 shows a fourth embodiment of the assembly 140, which is an extension of the third embodiment. In this case, the first chip 100 acts as a carrier for the second chip 200 and for a further chip 250, which is coupled to the first chip with solder balls 257. It is suitable, but not necessary herein that the solder balls 57, 257 are provided on the first chip 100.

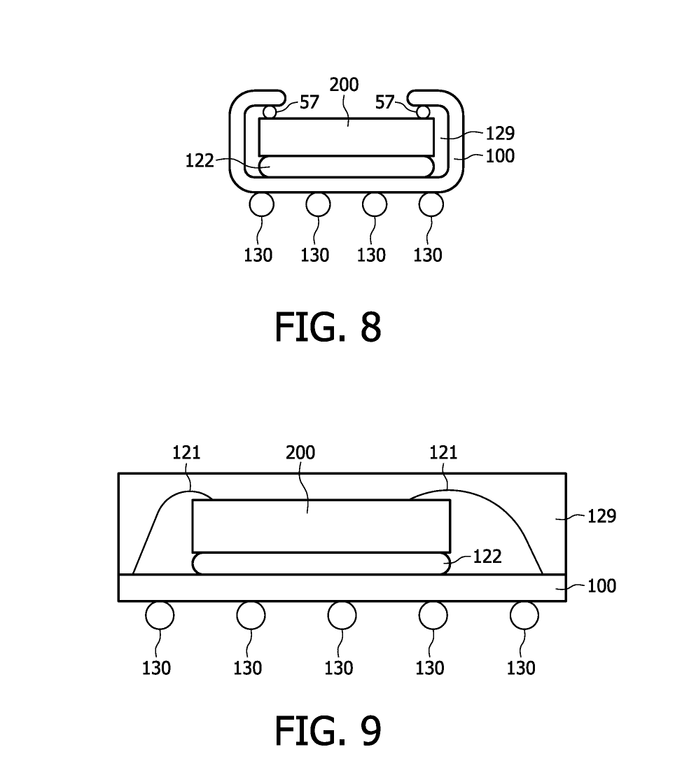

FIG. 8 shows a fifth embodiment of the assembly 140, in which the second chip 200 is attached to the first chip 100 with a die attach 122. The first chip 100 is bent thereafter, therewith constituting the interconnect to the solder balls 57 at the opposite side of the second chip 200. Any space between the first chip 100 and the second chip 200 is filled with any encapsulating material. It is observed that further modifications of such an assembly concept 150 are possible, particularly for applications in which it is desired that the second chip 200 includes an angle larger than 0° with the plane of the printed circuit board. Herein, the second chip 200 is assembled to the first chip 100 before the first chip 100 is bent. In a second step, the first chip is bent over a desired angle, so as to reorient the second chip 200. Finally, molding material is provided which solidifies the orientation of the second chip 200. The contact pads for external contacting are herein present in an area that is not bent, although this is not necessary.

FIG. 9 discloses a sixth embodiment of the assembly 140. Herein the electrical connections between the first chip 100 and the second chip 200 are constituted by wirebonds 121. This assembly 140 has the advantage that it is very similar to conventional ball grid array packages and nevertheless comprises a first chip 100 and a second chip 200.

In short, an assembly of a first chip 100 and a second chip 200, which first chip 100 is flexible and is provided with a first and a second resin layer 12,52 on opposite sides 1,2 of the chip 100, which allows to keep the first chip under compressive conditions, on which first and second side 1,2 respectively first side contact pads 33 and second side contact pads 31 are present, which first side contact pads 33 are coupled to corresponding contact pads 211 of the second chip 200, and which second side contact pads 31 are designed for external connection of the assembly.

1. An assembly of a first chip and a second chip, wherein the first chip is flexible and provided with a first and a second resin layer on opposite sides of the first chip to keep the first chip under compressive conditions, wherein first side contact pads and second side contact pads are present on a first and second sides respectively, wherein the first side contact pads are coupled to corresponding contact pads of the second chip, and wherein the second side contact pads are used for external connection of the assembly.

2. An assembly as claimed in claim 1, wherein the first side contact pads have a larger diameter than the second side contact pads.

3. An assembly as claimed in claim 1, wherein the first side contact pads and the second side contact pads are present on the first and the second resin layer respectively, and the first and second contact pads are electrically coupled to electrical elements in the first chip with vertical interconnects through said resin layers.

4. An assembly as claimed in claim 1, wherein the first side contact pads of the first chip and the corresponding contact pads of the second chip are facing each other.

5. An assembly as claimed in claim 1, wherein the second chip laterally extends beyond the first chip.

6. An assembly as claimed in claim 5, wherein the second chip has additional contact pads adjacent to those coupled to the first side contact pads of the first chip, wherein the additional contact pads are used for external connection of the assembly.

7. An assembly as claimed in claim 1, wherein the first and the second chip have equal lateral dimensions.

8. An assembly as claimed in claim 1, wherein an electronic device includes said assembly.

9. An assembly as claimed in claim 1, wherein the first chip acts as a carrier for the second chip.

10. An assembly as claimed in claim 1, wherein the second side contact pads care rerouted with respect to the first side contact pads.

11. An assembly as claimed in claim 1, wherein the first chip comprises protection circuits for protection of the second chip against electrostatic discharge.

12. An assembly as claimed in claim 1, wherein the first chip comprises a network of passive components.

13. A method of manufacturing an assembly of a first and a second chip, comprising:
attaching a first wafer having a semiconductor substrate with a plurality of the first chips to a carrier;
thinning the semiconductor substrate;
attaching a second wafer having a semiconductor substrate with a plurality of the second chips to the thinned semiconductor substrate of the first wafer; and
opening contact pads so as to enable external connection to the assembly, wherein—the first wafer is provided with first side contact pads and second side contacts, wherein the first side contacts are exposed after the thinning of the semiconductor substrate and are electrically coupled to bond pads in the second wafer, and
the assembly is detached from the carrier in order to open the top side contact pads for external connection.

14. A method as claimed in claim 14, wherein the first and the second wafers are provided with trenches that are filled with a filling material and after thinning extend from the first side to the second side of the wafers, and wherein the assembly is customized by removal of the filling material from the trenches and subsequent removal of the assembly from the carrier.
